(19) United States
(12) Patent Application Publication
(10) Pub. No.: US 2020/0123646 A1
(43) Pub. Date: Apr. 23, 2020

(54) VAPOR DEPOSITION PARTICLE EJECTING DEVICE, VAPOR DEPOSITION APPARATUS, AND VAPOR DEPOSITION FILM FORMING METHOD

(71) Applicant: Sharp Kabushiki Kaisha, Sakai City, Osaka (JP)

(72) Inventor: Masao NISHIGUCHI, Sakai City (JP)

(21) Appl. No.: 16/472,223

(22) PCT Filed: Sep. 28, 2017
(86) PCT No.: PCT/JP2017/035297

§ 371 Date: Jun. 21, 2019

(51) Int. Cl. C23C 14/24; H01L 51/00

(52) U.S. Cl. CPC C23C 14/24; H01L 51/0008

(57) ABSTRACT

The vapor deposition particle ejecting device includes a second vapor deposition source, a first vapor deposition source and a third vapor deposition source sandwiching the second vapor deposition source in a Y-axis direction. The first and the third vapor deposition sources are each provided with a plurality of nozzles that are inclined toward the second vapor deposition source and are arranged along an X-axis direction. The second vapor deposition source is provided with a plurality of nozzles and a plurality of nozzles that are respectively inclined toward the first vapor deposition source and the third vapor deposition source and are arranged along the X-axis direction.

### TECHNICAL FIELD

The disclosure relates to a vapor deposition particle ejecting device used for co-evaporation of a host and a dopant, a vapor deposition apparatus including the vapor deposition particle ejecting device, and a vapor deposition film forming method using the vapor deposition particle ejecting device.

### BACKGROUND ART

Generally, vacuum vapor deposition is used for forming a light-emitting layer that is provided between a pair of electrodes, and forms a light-emitting element in a flat panel display such as an Electro luminescence (EL) display apparatus including the light-emitting element.

Generally, a vapor deposition material used for the light-emitting layer is formed from a two-component system including a host in charge of transporting holes and electrons, and a dopant in charge of light emission, so that a higher light emission efficiency can be achieved. Preferably, the dopant is uniformly dispersed in the host that is a main component.

The host and the dopant are ejected from different vapor deposition sources. The vapor deposition sources are provided with nozzles having ejection ports for ejecting these vapor deposition materials. These vapor deposition material are simultaneously ejected toward a film formed substrate from the vapor deposition source, to be co-evaporated. As a result, a vapor deposition film including both materials is formed as the light-emitting layer on the film formed substrate. (see PTL1 for example).

### CITATION LIST

### Patent Literature

PTL 1: JP 2012-146658 A (published on Aug. 2, 2012)

### SUMMARY

### Technical Problem

Generally, a mix ratio of the dopant to the host is low (1 to 20%). The mix ratio between the host and the dopant is generally adjusted with a film formation rate. As a result, the dopant vapor deposition source has a low film formation rate compared with the host vapor deposition source and a lower internal pressure therein compared with the host vapor deposition source.

In a case where the internal pressure of the vapor deposition source is insufficient, uniform film thickness distribution cannot be achieved. In view of this, to achieve the internal pressure of the vapor deposition source for dopant that is equivalent to the internal pressure of the host vapor deposition source, the dopant vapor deposition source needs to be set to have a smaller nozzle diameter than the host vapor deposition source.

However, a smaller nozzle diameter results in a higher directivity of a vapor deposition flow ejected from the vapor deposition source. As a result, a host with a relatively low directivity of the vapor deposition flow is mixed with a dopant with a relatively high directivity of the vapor deposition flow, resulting in non-uniform mixture between the host and the dopant.

The disclosure is made in view of the problem described above, and an object of the disclosure is to provide a vapor deposition particle ejecting device, a vapor deposition apparatus, and a vapor deposition film forming method with which a host and a dopant can be co-evaporated with the dopant uniformly dispersed in the host.

### Solution to Problem

To solve the problem described above, a vapor deposition particle ejecting device according to one aspect of the disclosure includes a vapor deposition source for dopant ejecting a dopant as vapor deposition particles, and a first vapor deposition source for host and a second vapor deposition source for host ejecting a host as vapor deposition particles and are arranged side by side in a first direction with the first vapor deposition source for host and the second vapor deposition source for host sandwiching the vapor deposition source for dopant. The first vapor deposition source for host is provided with a plurality of first nozzles linearly arranged along a second direction orthogonal to the first direction, the first nozzles being inclined toward the vapor deposition source for dopant. The second vapor deposition source for host is provided with a plurality of second nozzles arranged along the second direction, the second nozzles being inclined toward the vapor deposition source for dopant. The vapor deposition source for dopant is provided with a plurality of third nozzles linearly arranged along the second direction, the third nozzles being inclined toward the first vapor deposition source for host, and with a plurality of fourth nozzles linearly arranged along the second direction, the fourth nozzles being inclined toward the second vapor deposition source for host.

To solve the problem described above, a vapor deposition apparatus according to one aspect of the disclosure includes the vapor deposition particle ejecting device according to one aspect of the disclosure. The host and the dopant are co-evaporated by moving at least one of the vapor deposition particle ejecting device and a film formed substrate, arranged while facing each other, along the first direction relative to the other.

To solve the problem described above, a vapor deposition film forming method according to one aspect of the disclosure for forming a vapor deposition film including a host and a dopant on a film formed substrate, the method including co-evaporating the host and the dopant by moving at least one of the vapor deposition particle ejecting device according to one aspect of the disclosure and the film formed substrate, arranged while facing each other, along the first direction relative to the other.

### Advantageous Effects of Disclosure

One aspect of the disclosure can provide a vapor deposition particle ejecting device, a vapor deposition apparatus, and a vapor deposition film forming method with which a host and a dopant can be co-evaporated with the dopant uniformly dispersed in the host.

### BRIEF DESCRIPTION OF DRAWINGS

FIG. 1A is a perspective view illustrating a schematic configuration of a vapor deposition particle ejecting device according to a first embodiment of the disclosure. FIG. 1B is a perspective view illustrating a schematic configuration of a main part of a first vapor deposition source in the vapor deposition particle ejecting device according to the first embodiment of the disclosure. FIG. 1C is a partially broken perspective view illustrating a schematic configuration of a second vapor deposition source in the vapor deposition particle ejecting device according to the first embodiment of the disclosure.

FIG. 2 is a perspective view illustrating a schematic configuration of a main part of a vapor deposition apparatus including the vapor deposition particle ejecting device according to the first embodiment of the disclosure.

FIG. 3A is a cross-sectional view illustrating a schematic configuration of a main part of the vapor deposition apparatus including the vapor deposition particle ejecting device according to the first embodiment of the disclosure. FIG. 3B is a cross-sectional view illustrating a schematic configuration of the second vapor deposition source in the vapor deposition particle ejecting device according to the first embodiment of the disclosure.

FIG. 4 is a diagram illustrating directivity of a vapor deposition flow formed by vapor deposition particles ejected from host nozzles and dopant nozzles.

FIG. 5 is a graph illustrating relationship between the distance in a Y-axis direction from a center position of a film formed substrate and a relative film thickness of each of a vapor deposition film including a host and a vapor deposition film including a dopant formed in Example 1.

FIG. 6 is a cross-sectional view illustrating a schematic configuration of a main part of a vapor deposition particle ejecting device according to Comparative Example 1 as well as the film formed substrate.

FIG. 7 is a graph illustrating relationship between the distance in the Y-axis direction from the center position of the film formed substrate and a relative film thickness of each of a vapor deposition film including a host and a vapor deposition film including a dopant formed in Comparative Example 1.

FIG. 8 is a cross-sectional view illustrating the schematic configuration of a main part of a vapor deposition particle ejecting device according to Comparative Example 2 as well as the film formed substrate.

FIG. 9 is a graph illustrating relationship between the distance in the Y-axis direction from the center position of the film formed substrate and a relative film thickness of each of a vapor deposition film including a host and a vapor deposition film including a dopant formed in Comparative Example 2.

FIG. 10 is a graph illustrating relationship between a distance in the Y-axis direction from a center position of a film formed substrate and a mix ratio of a dopant to a host in a thickness direction of a co-evaporation film including the host and the dopant formed by vapor deposition particle ejecting devices according to Example 1 and Comparative Examples 1 and 2, with a mix ratio of the dopant to the host set to be 100%.

### DESCRIPTION OF EMBODIMENTS

### First Embodiment

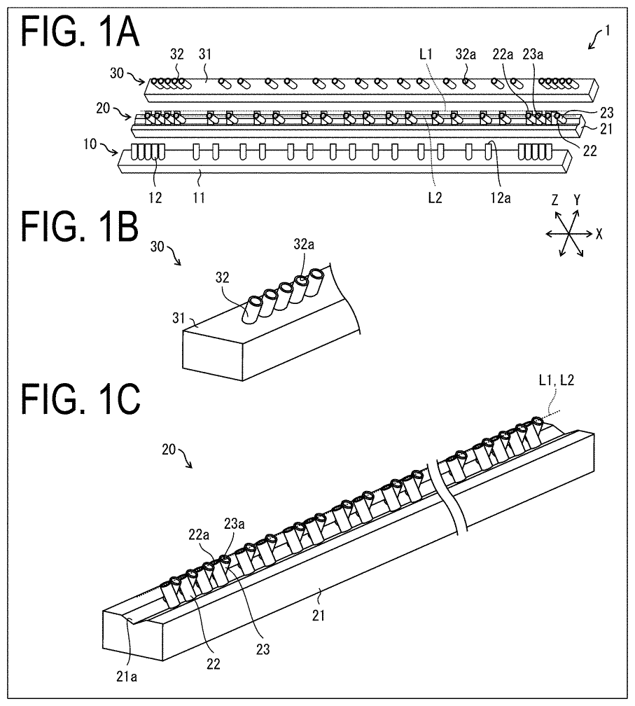

A description follows regarding one aspect of the disclosure, with reference to FIGS. 1A to 1C through FIG. 10.

FIG. 1A is a perspective view illustrating a schematic configuration of a vapor deposition particle ejecting device 1 according to the present embodiment. FIG. 1B is a perspective view illustrating a schematic configuration of a main part of a first vapor deposition source 10 in the vapor deposition particle ejecting device 1 according to the embodiment. FIG. 1C is a partially broken perspective view illustrating a schematic configuration of a second vapor deposition source 20 in the vapor deposition particle ejecting device 1 according to the embodiment.

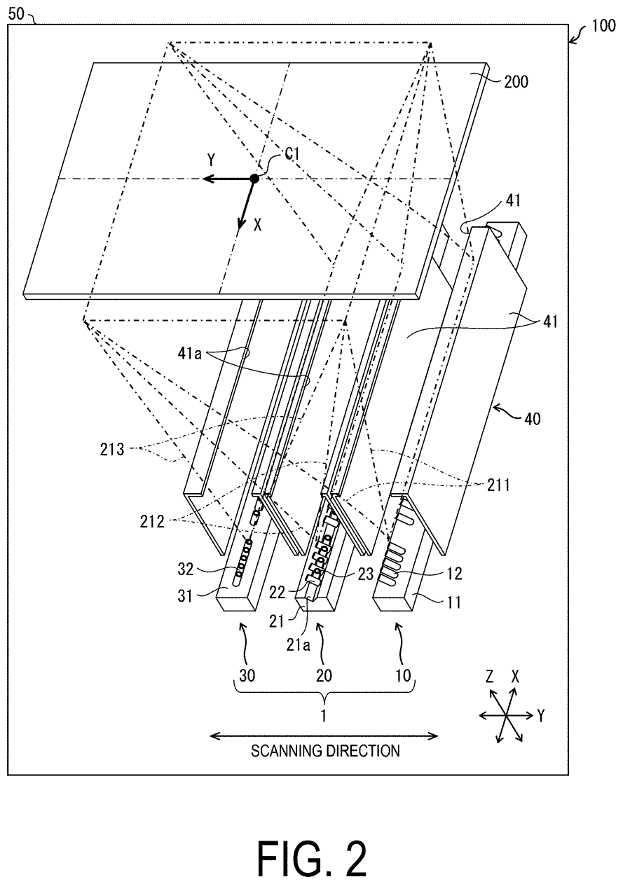

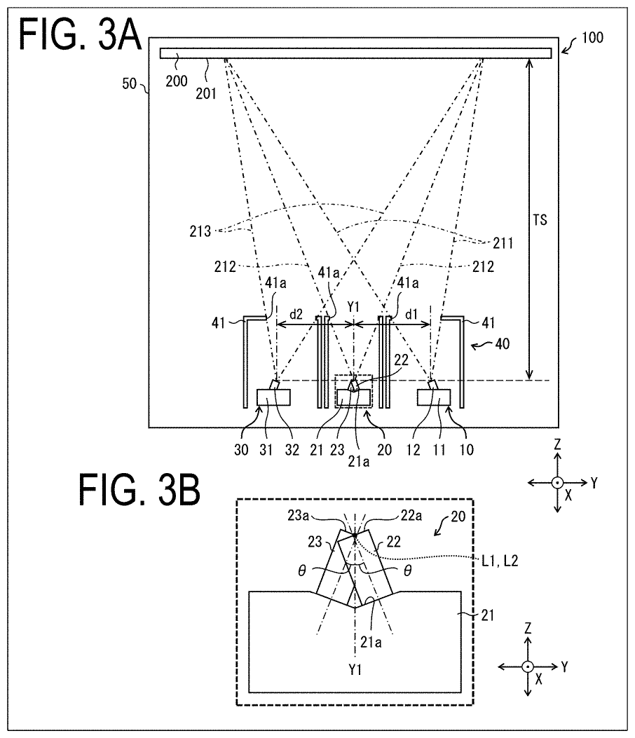

FIG. 2 is a perspective view illustrating a schematic configuration of a main part of a vapor deposition apparatus 100 including the vapor deposition particle ejecting device 1 according to the embodiment. FIG. 3A is a cross-sectional view illustrating a schematic configuration of a main part of the vapor deposition apparatus 100 including the vapor deposition particle ejecting device 1 according to the embodiment. FIG. 3B is a cross-sectional view illustrating a schematic configuration of the second vapor deposition source 20 in the vapor deposition particle ejecting device 1 according to the embodiment.

In the description below, a Y-axis direction (first direction) corresponds to an arrangement direction of the first vapor deposition source 10, the second vapor deposition source 20, and a third vapor deposition source 30 and a horizontal direction-axis direction along a direction of scanning of a film formed substrate 200 by the vapor deposition particle ejecting device 1. An X-axis direction (second direction) corresponds to an arrangement direction of nozzles 12, 22, 23, and 32 of the first vapor deposition source 10, the second vapor deposition source 20, and the third vapor deposition source 30 and a horizontal direction-axis direction along a direction orthogonal to the scanning direction of the film formed substrate 200. A Z-axis direction corresponds to a normal direction of a film formed surface 201 of a film formed substrate 200 and an orthogonal direction axis (upward and downward direction axis) direction orthogonal to the X axis and the Y axis. In the description, a side pointed by an upward arrow in the Z-axis direction is the upper side unless otherwise specified, for the convenience of description.

As illustrated in FIG. 2 and FIG. 3A, the vapor deposition apparatus 100 according to the embodiment is used for forming a vapor deposition film (not illustrated) on the film formed substrate 200.

An example of the film formed substrate 200 includes a Thin Film Transistor (TFT) substrate used for an organic EL element substrate in an organic EL display device. An example of the vapor deposition film includes a light-emitting layer in the organic EL element. A vapor deposition material used for vapor deposition of the light-emitting layer is formed from a two component system with a host in charge of transporting holes and electrons and a dopant in charge of light emission. The vapor deposition apparatus 100 is used as an apparatus for manufacturing an organic EL display device.

The vapor deposition apparatus 100 includes a vacuum chamber 50, the vapor deposition particle ejecting device 1, a limiting plate unit 40, a substrate holder (not illustrated) that holds the film formed substrate 200, a mask holder (not illustrated) that holds a vapor deposition mask (not illustrated), and a conveyance device (not illustrated) that enables relative positions of the vapor deposition particle ejecting device 1 and film formed substrate 200 to be varied. The vapor deposition particle ejecting device 1, the limiting plate unit 40, the substrate holder, the mask holder, and the conveyance device are provided in the vacuum chamber 50. In the vacuum chamber 50, the vapor deposition particle ejecting device 1 is disposed to face the film formed surface 201 of the film formed substrate 200 with a vapor deposition mask (not illustrated) provided in between.

As illustrated in FIGS. 1A to 1C through FIGS. 3A and 3B, the vapor deposition particle ejecting device 1 according to the embodiment includes the first vapor deposition source 10 (a first host vapor deposition source), the second vapor deposition source 20 (dopant vapor deposition source), and the third vapor deposition source 30 (second host vapor deposition source).

The first vapor deposition source 10 and the third vapor deposition source 30 each heat and thus vaporize the host under high vacuum, and eject the resultant material as vapor deposition particles toward the film formed substrate 200. The second vapor deposition source 20 heats and thus vaporizes the dopant under high vacuum, and ejects the resultant material as vapor deposition particles toward the film formed substrate 200. The first vapor deposition source 10, the second vapor deposition source 20, and the third vapor deposition source 30 are arranged side by side in the Y-axis direction, that is, the scanning direction of the film formed substrate 200, with the first vapor deposition source 10 and the third vapor deposition source 30 sandwiching the second vapor deposition source 20. The vaporization of the host or the dopant as used herein includes evaporation of the vapor deposition material (host or dopant) if the material is liquid and sublimation of the vapor deposition material if the material is solid.

The first vapor deposition source 10 is a long vapor deposition source with a linear form (rectangular form) in plan view, which is also referred to as a line source or a linear source.

As illustrated in FIGS. 1A and 1B, FIG. 2, and FIG. 3A, the first vapor deposition source 10 includes a container section 11 that contains the host vaporized to be vapor deposition particles 211 and a plurality of nozzles 12 (first nozzles) that eject the vapor deposition particles 211 in the container section 11 to the outside.

The container section 11 has a length in the X-axis direction longer than that in the Y-axis direction to be formed as a rectangular pillar shaped long container with a linear shape (rectangular shape) in plan view.

For example, the container section 11 may be a container that directly contains the host that is not vaporized (that is, the host before the vaporization), and may be a container that has a load lock pipe through which the host that has been vaporized or before the vaporization is supplied from the outside.

For example, the first vapor deposition source 10 may incorporate a crucible (not illustrated) that is a heat resisting container that contains the host and a heater (not illustrated) (heat source) that heats and vaporizes the host inside the crucible. The internal of the container section 11 is heated to or above the vaporizing temperature of the host, so as not to be clogged by the host.

The container section 11 has one surface on which the plurality of nozzles 12 are linearly arranged in a single array along the X-axis direction orthogonal to the scanning direction.

The nozzles 12 are formed of tubular straight pipes having an annular cross-sectional shape. Each of the nozzles 12 protrudes from the one surface of the container section 11 while being slightly inclined, toward the second vapor deposition source 20, relative to the normal direction that is the upright direction. Each of the nozzles 12 has an upper end side opening end face orthogonal to the axis direction of the nozzle 12.

The nozzles 12 have the same nozzle diameter, the same nozzle inclination angle θ, and the same nozzle length (the length in the nozzle-axis direction). Thus, the upper end side opening end faces of the nozzles 12 are arranged in a single array (on the same axis) along the X-axis direction.

The nozzle 12 is connected to the container section 11 to be in communication with the internal space of the container section 11. The nozzle 12 has a lower end side opening end face (not illustrated) that is connected to the container section 11 to be used as a vapor deposition particle inlet. The upper end side opening end face of the nozzle 12 is used as a vapor deposition particle outlet 12a (ejection port). The center of the upper end side opening end face of the nozzle 12 matches the center of the ejection port. The nozzle 12 ejects the vapor deposition particles 211, entered into the nozzle 12 through the vapor deposition particle inlet, toward the film formed substrate 200 through the vapor deposition particle outlet 12a.

The third vapor deposition source 30 has the same configuration as the first vapor deposition source 10. Thus, in this description, the first vapor deposition source 10, the container section 11, the nozzle 12 (first nozzle), the vapor deposition particle outlet 12a, and the vapor deposition particles 211 can respectively be read as a third vapor deposition source 30, a container section 31, a nozzle 32 (second nozzle), a vapor deposition particle outlet 32a, and vapor deposition particles 213.

The first vapor deposition source 10 and the third vapor deposition source 30 are arranged to sandwich the second vapor deposition source 20, so that the nozzles 12 and the nozzles 32 are inclined in directions toward each other (that is, directions in which their nozzle axes cross each other).

The second vapor deposition source 20 is similar to the first vapor deposition source 10 and the third vapor deposition source 30 in that it is also a long vapor deposition source that has a linear shape (rectangular shape) in plan view, and is also referred to as a line source or a linear source.

As illustrated in FIGS. 1A and 1C, FIG. 2, and FIGS. 3A and 3B, the second vapor deposition source 20 includes a container section 21 that contains the dopant vaporized to be the vapor deposition particles 212 and a plurality of nozzles 22 and 23 that eject the vapor deposition particles 212 in the container section 21 to the outside.

The container section 21 has a length in the X-axis direction longer than that in the Y-axis direction to be formed as a rectangular pillar shaped long container with a linear shape (rectangle shape) in plan view.

For example, the container section 21 may be a container that directly contains the dopant that is not vaporized (that is, the dopant before the vaporization), and may be a container that has a load lock pipe through which the dopant that has been vaporized or before the vaporization is supplied from the outside.

For example, the second vapor deposition source 20 may incorporate a crucible (not illustrated) that is a heat resisting container that contains the dopant and a heater (not illustrated) (heat source) that heats and vaporizes the dopant inside the crucible. The internal of the container section 21 is heated to or above the vaporizing temperature of the dopant, so as not to be clogged by the dopant.

The container section 21 has one surface (for example, an upper surface) on which a plurality of nozzles 22 (fourth nozzles) are linearly arranged in a single array along the X-axis direction orthogonal to the scanning direction and a plurality of nozzles 23 (third nozzles) are linearly arranged in a single array along the X-axis direction. Thus, the container section 21 has the one surface on which an array of nozzles 22 including the plurality of nozzles 22 (hereinafter, referred to as “nozzles 22 array”) and an array of nozzles 23 including the plurality of nozzles 23 (hereinafter, referred to as “nozzles 23 array”) are arranged side by side in the Y-axis direction.

The nozzles 22 array is provided adjacent to the first vapor deposition source 10. The nozzles 23 array is provided adjacent to the third vapor deposition source 30.

The nozzles 22 and 23 are formed of tubular straight pipes having an annular cross-sectional shape as in the case of the nozzles 12 and 32.

The one surface of the container section 21 is provided with a V-shaped groove section 21a. The nozzles 22 stand on one of inclined surfaces (one of inner walls of the groove section) defining the groove section 21a with their nozzle axis being orthogonal to the inclined surface. The nozzles 23 stand on the other one of the inclined surfaces (the other one of the inner walls of the groove section) defining the groove section 21a with their nozzle axis being orthogonal to the inclined surface.

Thus, the nozzles 22 and 23 protrude from the respective one surfaces of the container section 21 while being slightly inclined, relative to the normal direction that is the upright direction, in the directions in which the axis direction of the nozzles 23 and the axis directions of the nozzle 22 cross each other. Specifically, the nozzle 23 is inclined toward the first vapor deposition source 10. The nozzle 22 is inclined toward the third vapor deposition source 30.

The nozzles 22 and 23 have the same nozzle diameter, the same nozzle inclination angle θ, and the same nozzle length. Thus, the upper end side opening end faces of the nozzles 22 are arranged in a single array (on the same axis) along the X-axis direction. Thus, the upper end side opening end faces of the nozzles 23 are arranged in a single array (on the same axis) along the X-axis direction. The nozzle length in the embodiment indicates the length in the axis direction of the nozzle (nozzle axis direction).

Thus, as illustrated in FIG. 1A, a line L1 connecting the centers of the upper end side opening end faces of the nozzles 22 adjacent to each other in the X-axis direction is a straight line. A line L2 connecting the centers of the upper end side opening end faces of the nozzles 23 adjacent to each other in the X-axis direction is also a straight line. The lines L1 and L2 are positioned on the same plane and extend in parallel along the X-axis direction.

The lines L1 and L2 are preferably to be matched (that is, in the same line) as illustrated in FIGS. 1C and 3B. In other words, as illustrated in FIG. 3B, the center position of the upper end side opening end face of the nozzle 22 in the Y-axis direction and the center position of the upper end side opening end face of the nozzle 23 in the Y-axis direction are preferably to be matched with a center position Y1 of the container section 21 in the Y-axis direction. The upper end side opening end faces of the nozzles 22 and the upper end side opening end faces of the nozzles 23 are alternately arranged in a single array along the X-axis direction.

The groove section 21a is formed with a predetermined nozzle inclination angle θ formed between the normal direction and the axis direction of the nozzle 22, 23. With the groove section 21a including the inclined surfaces facing each other formed on the one surface of the container section 21 and the nozzles 22 and 23 provided to stand to be orthogonal to the inclined surfaces of the groove section 21a as described above, the nozzle inclination angle θ formed between the normal direction and the axis direction of nozzles 22, 23 can be easily set to be a desired angle that is uniform in each of the nozzle arrays.

However, the embodiment is not limited to this, and the nozzles 22 and 23 may be connected to one surface of the container section 21 while being inclined, without forming the groove section 21a on the one surface of the container section 21. Alternatively, a groove section or a protrusion having inclined surfaces may be formed on one surface of each of the container sections 11 and 31, and the nozzles 12 and 31 may be formed on the inclined surfaces.

In the example illustrated in FIGS. 1A and 1C, FIG. 2, and FIGS. 3A and 3B, the groove section 21a has a V shape as described above. However, the embodiment is not limited thereto. The groove section 21a suffices in a case where the groove section 21a has inclined surfaces facing each other, and thus may have a recess shape with inner walls having inclined surfaces.

The nozzles 22 and 23 are connected to the container section 21 to be in communication with the internal space of the container section 21. The nozzle 22, 23 has a lower end side opening end face (not illustrated) that is connected to the container section 21 to be used as a vapor deposition particle inlet. The upper end side opening end face of the nozzle 22 is used as a vapor deposition particle outlet 22a (ejection port). The upper end side opening end face of the nozzle 23 is used as a vapor deposition particle outlet 23a. The center of the upper end side opening end face of the nozzle 22, 23 matches the center of the ejection port. The nozzles 22 and 23 eject the vapor deposition particle 212, entered into the nozzles 22 and 23 through the vapor deposition particle inlet, onto the film formed substrate 200 through the vapor deposition particle outlet 22a, 23a.

The host and the dopant are simultaneously ejected from the first vapor deposition source 10, the second vapor deposition source 20, and the third vapor deposition source 30 toward the film formed substrate 200 to be co-evaporated. As a result, a vapor deposition film including the host and the dopant is formed as a light-emitting layer on the film formed substrate 200.

In the first vapor deposition source 10, the second vapor deposition source 20, and the third vapor deposition source 30, the placement density of the nozzles 12, 22, 23, and 32 in an end portion of the container sections 11, 21 and 31 in the X-axis direction is set to be higher than that in a center portion of the container sections 11, 21 and 31, to suppress variation of the distribution of the vapor deposition film in the X-axis direction that is the longitudinal direction of the container sections 11, 21, and 31.

FIG. 2 and FIG. 3A illustrates an example of up deposition where the vapor deposition particle ejecting device 1 performs vapor deposition of the vapor deposition particles 211, 212, and 213 respectively in the first vapor deposition source 10, the second vapor deposition source 20, and the third vapor deposition source 30, from the lower side toward the upper side. Thus, an example where the nozzles 12, 22, 23, and 32 are each provided on the upper surface of a corresponding one of the container sections 11, 21, and 31. However, the embodiment is not limited thereto. For example, the nozzles 12, 22, 23, and 32 may each be provided on a lower surface of a corresponding one of the container sections 11, 21, and 31. The configuration in a case where the nozzles 12, 22, 23, and 32 are thus provided on the lower surfaces of the container sections 11, 21, and 31 can be suitably used for down deposition that is vapor deposition of the corresponding vapor deposition particle 211, 212, and 213 from the upper side toward the lower side.

FIGS. 1A to 1C and FIG. 2 illustrate an example where the nozzles 12, 22, 23 and 32 face each other in the Y-axis direction with the nozzle inclination angle θ formed between the normal direction and the axis direction of each of the nozzles 12, 22, 23 and 32 being uniform along each nozzle array. However, the embodiment is not limited thereto.

The nozzles 12, 22, 23 and 32 do not necessarily be provided in the same quantity, or to be provided facing each other to be linearly aligned as viewed in the Y-axis direction. The nozzles 12, 22, 23 and 32 may be arranged at positions to be shifted from each other as viewed in the Y-axis direction. Thus, the nozzles 12, 22, 23 and 32 may form different nozzle inclination angles θ in each nozzle array.

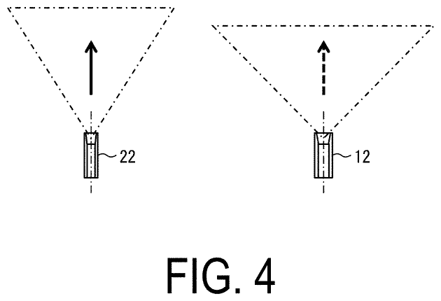

FIG. 4 is a diagram illustrating directivity of a vapor deposition flow formed by the vapor deposition particle ejected from the nozzle 12 and the nozzle 22.

As described above, the nozzle 22 and the nozzle 23 have the same nozzle diameter, the same nozzle inclination angle θ, and the same length in the nozzle-axis direction (nozzle length), and are only different from each other in the inclining direction. The nozzle 22 and the nozzle 23 respectively have the vapor deposition particle outlets 22a and 23a as their upper end side opening end faces being orthogonal to the nozzle-axis directions and formed to be true circles. Thus, the directivity of the vapor deposition flow formed by the vapor deposition particle ejected from the nozzle 23 is the same as the directivity of the vapor deposition flow formed by the vapor deposition particle ejected from the nozzle 22.

As described above, the nozzle 12 and the nozzle 32 have the same nozzle diameter, the same nozzle inclination angle θ, and the same length in the nozzle-axis direction (nozzle length), and are only different from each other in the inclining direction. The nozzle 12 and the nozzle 32 respectively have the vapor deposition particle outlets 12a and 32a as their upper end side opening end faces being orthogonal to the nozzle-axis directions and formed to be true circles. Thus, the directivity of the vapor deposition flow formed by the vapor deposition particle ejected from the nozzle 32 is the same as the directivity of the vapor deposition flow formed by the vapor deposition particle ejected from the nozzle 12.

Thus, the directivity of the vapor deposition flow formed by the vapor deposition particle ejected from the nozzle 23 and the directivity of the vapor deposition flow formed by the vapor deposition particle ejected from the nozzle 32 are omitted from the drawings.

FIG. 2 and FIG. 3A illustrate vapor deposition flow formed by the vapor deposition particles 212 as a combination of vapor deposition particles ejected from the nozzles 22 and 23 arranged while being inclined to have their nozzle axes crossing each other.

Generally, a mix ratio of the dopant to the host is low (1 to 20%). The mix ratio between the host and the dopant is generally adjusted with a film formation rate. In view of this, as illustrated in FIG. 4, the nozzles 22 and 23 are formed to have a nozzle diameter smaller than that of the nozzles 12 and 32. More specifically, the nozzles 22 and 23 are formed to have a higher aspect ratio than the nozzles 12 and 32. The aspect ratios as used herein is a ratio of the nozzle length in the nozzle-axis direction to the diameter of the nozzle (the nozzle length in the nozzle-axis direction/the diameter of the nozzle), wherein the nozzle length in the nozzle-axis direction is a length of a straight line between the centers of the upper and the lower end side opening end faces of the nozzle. Thus, the directivity of the vapor deposition flow formed by the vapor deposition particle ejected from the nozzles 22 and 23 is higher than the directivity of the vapor deposition flow formed by the vapor deposition particle ejected from the nozzles 12 and 32.

Still, the directivity of the vapor deposition flow can be suppressed in the embodiment with a plurality of nozzle arrays inclined in directions different from each other provided to the second vapor deposition source 20.

The embodiment is designed in such a manner that a combined component including dopant (first dopant component) and dopant (second dopant component) ejected from the second vapor deposition source 20 respectively through the nozzles 22 and the nozzles 23 match a combined component including host (first host component) ejected from the first vapor deposition source 10 and host (second host component) ejected from the third vapor deposition source 30.

Still, the directivity of the dopant can be set to be lower than that of the host, with the nozzles 12, 22, 23 and 32 set to be in a plurality of direction with various angles so that nozzle arrays have nozzle inclination angles θ different from each other as described above.

The known host and dopant that are used for a light-emitting layer in a light-emitting element can be used as the host and the dopant. The types and the combination of the host and the dopant are not particularly limited.

The vapor deposition particle ejecting device 1, the limiting plate unit 40, the vapor deposition mask (not illustrated), and the film formed substrate 200 are arranged in the vacuum chamber 50 in this order along the Z-axis direction with the corresponding components facing each other.

The vapor deposition apparatus 100 moves at least one of the vapor deposition particle ejecting device 1 and the film formed substrate 200 relative to the other to perform vapor deposition (co-evaporation of the host and the dopant) while scanning the film formed substrate 200. Thus, a light-emitting layer as a vapor deposition film (co-evaporation film including the host and the dopant) including the host ejected from the first vapor deposition source 10 and the third vapor deposition source 30 and the dopant ejected from the second vapor deposition source is formed (produced) on the film formed substrate 200. Thus, the relative positions of the vapor deposition particle ejecting device 1 and the limiting plate unit 40 are fixed.

The limiting plate unit 40 includes a plurality of limiting plates 41 that limit passage angles of the vapor deposition particle 211, 212, and 213 ejected from the nozzles 12, 22, 23, and 32.

The limiting plates 41 are provided along the Y axis direction while being separated from each other to be partitions among the vapor deposition sources 10, 20, and 30 in plan view. The limiting plate 41 extend in parallel with each other in the X-axis direction. Thus, the limiting plate unit 40 includes a plurality of limiting plate openings 41a along the X-axis direction.

As illustrated in FIG. 2 and FIG. 3A, the host ejected from the first vapor deposition source 10 is vapor deposited as the vapor deposition particles 211 on the film formed substrate 200 after passing through the limiting plate opening 41a between the adjacent limiting plates 41 provided along the longitudinal direction of the first vapor deposition source 10 and then passing through the mask opening formed in the vapor deposition mask. Similarly, the host ejected from the third vapor deposition source 30 is vapor deposited as the vapor deposition particles 213 on the film formed substrate 200 after passing through the limiting plate unit opening 41a between the adjacent limiting plates 41 provided along the longitudinal direction of the third vapor deposition source 30 and then passing through the mask opening formed in the vapor deposition mask. The dopant ejected from the second vapor deposition source 20 is vapor deposited as the vapor deposition particles 212 on the film formed substrate 200 after passing through the limiting plate opening 41a between the adjacent limiting plate units 41 provided along the longitudinal direction of the second vapor deposition source 20 and then passing through the mask opening formed in the vapor deposition mask.

The limiting plate unit 40 selectively blocks (captures) the vapor deposition particles 211, 212, and 213 made incident on the limiting plate unit 40 based on the incident angle. Thus, the limiting plate unit 40 limits the incident angles of the vapor deposition particles 211, 212, and 213, incident on the mask opening of the vapor deposition mask within a predetermined range, and thus the vapor deposition particles 211, 212, and 213 from inclined directions are prevented from attaching to the film formed substrate 200.

### Advantageous Effects

The advantageous effects of the vapor deposition particle ejecting device 1 according to the embodiment are described below in detail with reference to the film thickness distribution as well as a result of measuring a mix ratio of the dopant to the host in the thickness of the direction of the vapor deposition film formed, in Examples and Comparative Examples.

### Example 1

In this example, as illustrated in FIGS. 2 and 3A, the vapor deposition particle ejecting device 1 and the limiting plate unit 40 according to the embodiment were arranged to face the file formed substrate 200 in the vacuum chamber 50, and vapor deposition films were each formed on the film formed substrate 200 by vapor deposition particles ejected from a corresponding one of the nozzles 12, 22, 23 and 32 with the film formed substrate 200 and the vapor deposition particle ejecting device 1 fixed.

The vapor deposition particle ejecting device 1 and the film formed substrate 200 are arranged in such a manner that the first vapor deposition source 10, the second vapor deposition source 20, and the third vapor deposition source 30 are each arranged in parallel with one side of the film formed substrate 200 with a center position C1 of the film formed substrate 200 matching the center position of the second vapor deposition source 20.

The container section 21 and the nozzles 22 and 23 of the second vapor deposition source 20 were formed to be linearly symmetrical about the X-axis direction and the Y-axis direction in this state. The vapor deposition particle ejecting device 1 used in the example was formed to have the container sections 11, 21, and 31 having the same length in the X-axis direction and having the X-axis direction end faces linearly aligned along the Y-axis direction, and to have nozzles 12, 22, 23 and 32 adjacent to each other in the Y-axis direction linearly aligned along the Y-axis direction, as illustrated in FIG. 1A and FIG. 2.

The nozzles 12, 22, 23 and 32 were set to have the same nozzle inclination angle θ. In this example, the nozzle inclination angle θ was 20°. As illustrated in FIG. 3B, the lengths of the nozzles 12, 22, 23 and 32 in the nozzle-axis direction are set in such a manner that the center position of the upper end side opening end face (vapor deposition particle outlet 22a) of the nozzle 22 in the Y-axis direction and the center position of the upper end side opening end face (vapor deposition particle outlet 23a) of the nozzle 23 in the Y-axis direction match a center position Y1 of the container section 21 in the Y-axis direction, and that a pitch between the nozzle 12 and the nozzle 22, 23 adjacent to each other in the Y-axis direction and a pitch between the nozzle 32 and the nozzle 22, 23 adjacent to each other in the Y-axis direction are each set to be 120 mm.

The pitch between the nozzle 12 and the nozzle 22, 23 adjacent to each other in the Y-axis direction is a distance between the center position of the vapor deposition particle outlet 12a of the nozzle 12 in the Y-axis direction and the center position of the vapor deposition particle outlet 22a, 23a of the nozzle 22, 23 in the Y-axis direction, adjacent to each other in the Y-axis direction. The pitch between the nozzle 32 and the nozzle 22, 23 adjacent to each other in the Y-axis direction is a distance between the center position of the vapor deposition particle outlet 32a of the nozzle 32 in the Y-axis direction and the center position of the vapor deposition particle outlet 22a, 23a of the nozzle 22, 23 in the Y-axis direction, adjacent to each other in the Y-axis direction.

A distance TS between the film formed surface 201 of the film formed substrate 200 and the center position of the upper end side opening end face of each of the nozzles 12, 22, 23 and 32 in the Y-axis direction, in the Z-axis direction, was set to be 500 mm.

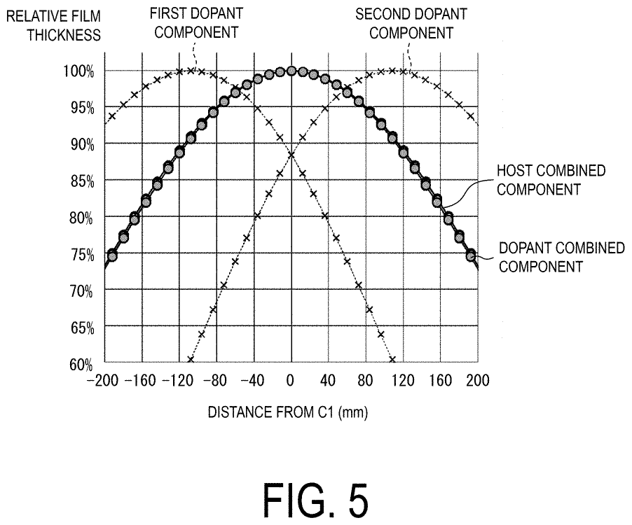

Then, a known film thickness measurement device was used to optically measure the film thickness of each vapor deposition film, and at a certain interval, the variation among the vapor deposition films in the relative film thickness in the Y-axis direction was measured. FIG. 5 illustrates the result of this measurement.

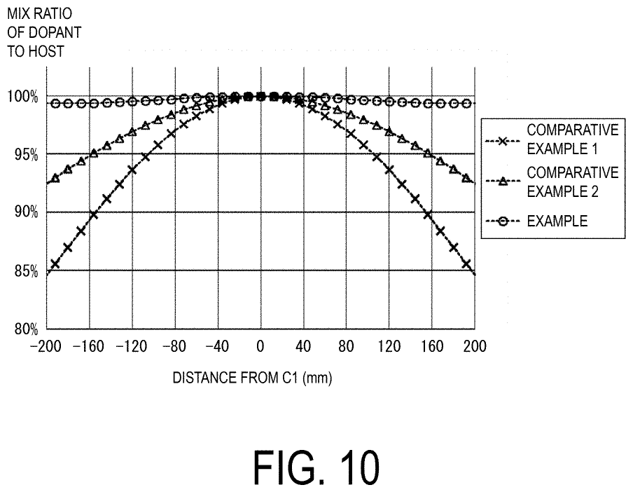

As described above, the vapor deposition film (the co-evaporation film including the host and the dopant) was formed with the mix ratio of the dopant to the host being 100% (thus, the mix ratio of dopant/host=1) and with the film formed substrate 200 and the vapor deposition particle ejecting device 1 fixed as described above. Then, variation of the mix ratio of the dopant to the host along the thickness direction of the vapor deposition film was measured along the Y-axis direction. FIG. 10 illustrates a result of this measurement along with results in Comparative Examples 1 and 2 as described later.

FIG. 5 is a graph illustrating relationship between the distance in the Y-axis direction from the center position C1 of the formed substrate 200 and a relative film thickness of the vapor deposition film including the host and the vapor deposition film including the dopant formed in Example 1.

Specifically, in FIG. 5, the coordinate origin corresponds to the center position C1 of the film formed substrate 200 immediately above the center position Y1 of the container section 21 in the Y-axis direction in the second vapor deposition source 20.

The relative film thickness of the vapor deposition films in FIG. 5 is a relative thickness of the vapor deposition film made of host with the maximum film thickness being 100%, and a relative thickness of the vapor deposition film made of dopant with the maximum film thickness being 100%, the films being formed on the film formed substrate 200 with the film formed substrate 200 and the vapor deposition particle ejecting device 1 fixed.

In FIG. 5, the relative film thickness indicated by the first dopant component indicates the relative film thickness of the vapor deposition film formed by the dopant ejected from the nozzle 22. The relative film thickness indicated by the second dopant component indicates the relative film thickness of the vapor deposition film formed by the dopant ejected from the nozzle 23. The relative film thickness indicated by the dopant combined component indicates the relative film thickness of the vapor deposition film formed by the dopant ejected from the nozzle 22 and the dopant ejected from the nozzle 23. The relative film thickness indicated by the host combined component indicates the relative film thickness of a vapor deposition film formed by host ejected from the first vapor deposition source 10 and host ejected from the second vapor deposition source 20.

As illustrated FIG. 5, in this example, the film thickness distribution of the host combined component in the Y-axis direction substantially overlap with the film thickness distribution of the dopant combined component in the Y-axis direction. Thus, in this example, the directivity of the combined component including hosts ejected from the nozzles 12 and 32 in the Y-axis direction is substantially the same as the directivity of the combined component including dopants ejected from the nozzles 22 and 23 in the Y-axis direction. Thus, in this example, the directivity of the dopant in the Y-axis direction can be suppressed to be close to the directivity of the host in the Y-axis direction, with a multi-array structure achieved by dopant nozzles in the second vapor deposition source 20 inclined relative to the film formed substrate 200 in directions toward the first vapor deposition source 10 and the third vapor deposition source 30.

As described above, FIG. 5 illustrates a film thickness distribution of a deposition film formed (fixed forming) with the film formed substrate 200 and the vapor deposition particle ejecting device 1 fixed so that the vapor deposition particle ejecting device makes no scanning action or movement. The vapor deposition achieved by making the vapor deposition particle ejecting device 1 perform scanning action along the Y-axis direction and swinging action, results in a film thickness uniform in the Y-axis direction.

### Comparative Example 1

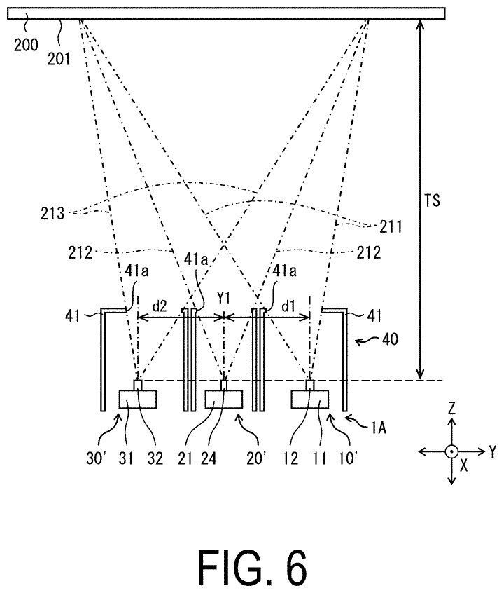

Comparative Example 1 is the same as Example 1 except that a vapor deposition particle ejecting device 1A illustrated in FIG. 6 is used instead of the vapor deposition particle ejecting device 1. Thus, the vapor deposition film were formed (fixed forming) by the vapor deposition particle ejected from nozzles 12, 24, and 32 as described later, and the film thicknesses of the vapor deposition films were measured as in a case where the vapor deposition particle ejecting device 1 is used.

FIG. 6 is a cross-sectional view illustrating the schematic configuration of the main part of the vapor deposition particle ejecting device 1A according to Comparative Example 1 as well as the film formed substrate 200.

The vapor deposition particle ejecting device 1A includes a first vapor deposition source 10′, a second vapor deposition source 20′, and a third vapor deposition source 30′ instead of the first vapor deposition source 10, the second vapor deposition source 20, and the third vapor deposition source 30 in the vapor deposition particle ejecting device 1. The first vapor deposition source 10′ has the same configuration as the first vapor deposition source 10 excepts that the nozzle 12 is standing straight. The third vapor deposition source 30′ has the same configuration as the third vapor deposition source 30 excepts that the nozzle 31 is standing straight. The second vapor deposition source 20′ has the same configuration as the second vapor deposition source 20 except that the container section 21 has a flat upper surface and that a plurality of nozzles 24 standing straight are linearly aligned along the X-axis direction orthogonal to the scanning direction. Conditions other than these are the same as those in Example 1.

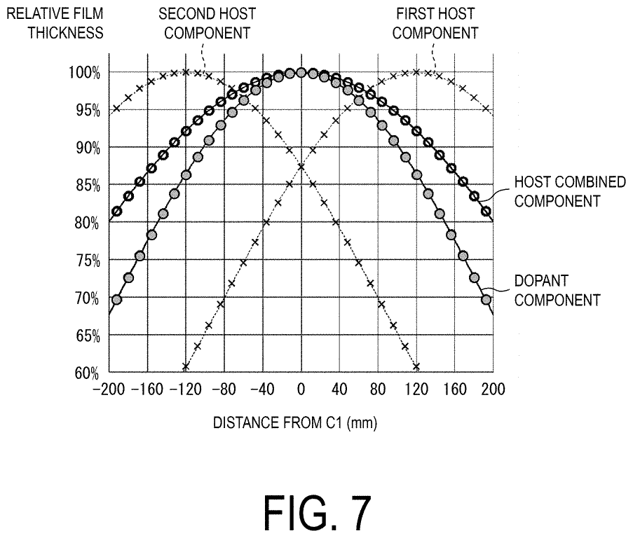

Then, a known film thickness measurement device was used to optically measure the film thickness of each vapor deposition film, and at a certain interval, the variation among the vapor deposition films in the relative film thickness in the Y-axis direction was measured. FIG. 7 illustrates the result of this measurement.

As described above, the vapor deposition film was formed with the mix ratio of the dopant to the host being 100% (thus, the mix ratio of dopant/host=1) and with the film formed substrate 200 and the vapor deposition particle ejecting device 1 as described above. Then, variation of the mix ratio of the dopant to the host along the thickness direction of the vapor deposition film was measured along the Y-axis direction. FIG. 10 illustrates a result of this measurement along with results in Example 1 and Comparative Example 2 as described later.

FIG. 7 is a graph illustrating relationship between the distance in the Y-axis direction from the center position C1 of the formed substrate 200 and a relative film thickness of the vapor deposition film including the host, and the vapor deposition film including the dopant formed in Comparative Example 1.

In FIG. 7, the coordinate origin corresponds to the center position C1 of the film formed substrate 200 immediately above the center position Y1 of the container section 21 in the Y-axis direction in the second vapor deposition source 20′. The center position Y1 of the container section 21 of the second vapor deposition source 20′ in the Y-axis direction corresponds to the center position of the upper end side opening end face of the nozzle 24 in the Y-axis direction.

The relative film thickness of the vapor deposition films in FIG. 7 is a relative thickness of the vapor deposition film made of host with the maximum film thickness being 100%, and a relative thickness of the vapor deposition film made of dopant with the maximum film thickness being 100%, the films being formed on the film formed substrate 200 with the film formed substrate 200 and the vapor deposition particle ejecting device 1A fixed.

In FIG. 7, the relative film thickness indicated by the first host component indicates the relative film thickness of the vapor deposition film formed by the host ejected from the nozzle 12 of the first vapor deposition source 10′. The relative film thickness indicated by the second host component indicates the relative film thickness of the vapor deposition film formed by the host ejected from the nozzle 32 of the third vapor deposition source 30′. The relative film thickness indicated by the host combined component indicates the relative film thickness of a vapor deposition film formed by host ejected from the first vapor deposition source 10′ and host ejected from the second vapor deposition source 20′.

As described above, the dopant vapor deposition source for the co-evaporation using the host and the dopant involves a low film forming rate and insufficient pressure (internal pressure) therein. Thus, the vapor deposition film formed with the dopant vapor deposition source has film thickness distribution with low uniformity.

In a case where the host nozzle and the dopant nozzle have the same shape, the dopant nozzle is likely to result in nonuniform film thickness distribution due to the insufficient internal pressure. Thus, it is a common practice to form the dopant nozzle to have a nozzle diameter (more specifically, the aspect ratio described above) smaller than a nozzle diameter (more specifically, the aspect ratio described above) of the host nozzle. As a result, the directivity of dopant becomes higher than that of the host, that is, the directivity of the host is lower than that of the dopant.

The host involves a higher film forming rate which is likely to lead to a large amount of dispersed components due to collision among molecules, and thus is likely to result in a further reduction of directivity. The directivity of the dopant can further be increased by raising internal pressure with the nozzle diameter of the nozzle 24 set to be smaller than those of the nozzles 12 and 32 as illustrated in FIG. 6. Thus, the host inherently result in a distribution with lower directivity than the dopant, even in a case where a single linear source is used.

In the Comparative Example 1, the first vapor deposition source 10′ and the third vapor deposition source 30′ serving as the vapor deposition sources for host are disposed on both sides of the second vapor deposition source 20′ serving as the dopant vapor deposition source, whereby the directivity of the host in the Y-axis direction indicated by the host combined component becomes lower than that in the case where only a single host vapor deposition source is used.

As a result, Comparative Example 1 results in a larger difference between the directivity of the combined component including the hosts ejected from the nozzles 12 and 32 in the Y-axis direction and the directivity of the dopant ejected from the nozzle 24 becomes large as illustrated in FIG. 7.

### Comparative Example 2

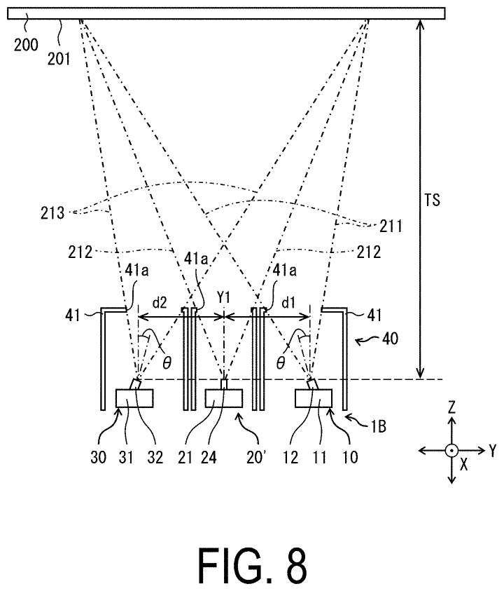

Comparative Example 2 is the same as Example 1 except that a vapor deposition particle ejecting device 1B illustrated in FIG. 8 is used instead of the vapor deposition particle ejecting device 1. Thus, the vapor deposition film are formed (fixed forming) by the vapor deposition particle ejected from nozzles 12, 24, and 32 as described later, and the film thicknesses of the vapor deposition films are measured as in a case where the vapor deposition particle ejecting device 1 is used.

FIG. 8 is a cross-sectional view illustrating the schematic configuration of the main part of the vapor deposition particle ejecting device 1B according to Comparative Example 2 as well as the film formed substrate 200.

The vapor deposition particle ejecting device 1B includes a second vapor deposition source 20′, which is the same as the second vapor deposition source 20′ illustrated in FIG. 6, instead of the second vapor deposition source 20 in the vapor deposition particle ejecting device 1. Conditions other than these are the same as those in Example 1.

In this comparative example, the nozzles 12 and 32 are each set to have the nozzle inclination angle θ of 15°, so that the combined component including the hosts ejected from the first vapor deposition source 10 and the third vapor deposition source 30 matches the directivity of the combined component including the dopants ejected from the second vapor deposition source 20′ including the nozzles 24 that are upright nozzles in the Y-axis direction. Thus, the host is ejected in an ejection direction close to that of the dopant. All other conditions are as those in Example 1.

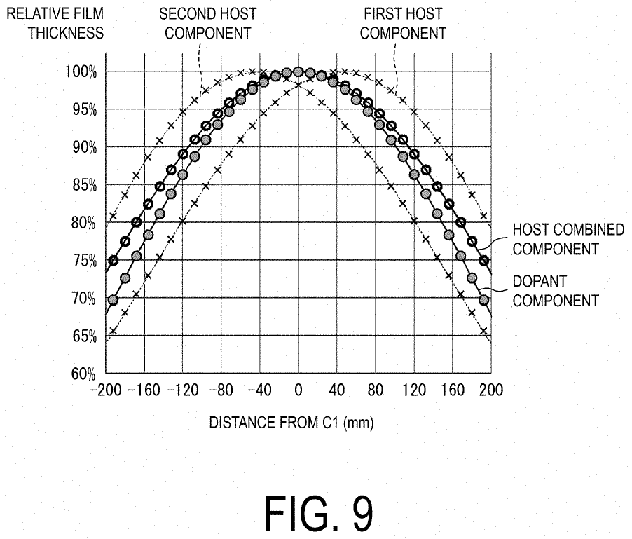

Then, a known film thickness measurement device was used to optically measure the film thickness of each vapor deposition film, and at a certain interval, the variation among the vapor deposition films in the relative film thickness in the Y-axis direction was measured. FIG. 9 illustrates the result of this measurement.

As described above, the vapor deposition film was formed with the mix ratio of the dopant to the host being 100% (thus, the mix ratio of dopant/host=1) and with the film formed substrate 200 and the vapor deposition particle ejecting device 1 as described above. Then, variation of the mix ratio of the dopant to the host along the thickness direction of the vapor deposition film was measured along the Y-axis direction. FIG. 10 illustrates a result of this measurement along with results in Example 1 and Comparative Example 1.

FIG. 9 is a graph illustrating relationship between the distance in the Y-axis direction from the center position C1 of the formed substrate 200 and a relative film thickness of the vapor deposition film including the host and the vapor deposition film including the dopant formed in Comparative Example 2.

Also in FIG. 9, the coordinate origin corresponds to the center position C1 of the film formed substrate 200 immediately above the center position Y1 of the container section 21 in the Y-axis direction in the second vapor deposition source 20′. The center position Y1 of the container section 21 of the second vapor deposition source 20′ in the Y-axis direction corresponds to the center position of the upper end side opening end face of the nozzle 24 in the Y-axis direction.

The relative film thickness of the vapor deposition films in FIG. 9 is a relative thickness of the vapor deposition film made of host with the maximum film thickness being 100%, and a relative thickness of the vapor deposition film made of dopant with the maximum film thickness being 100%, the films being formed on the film formed substrate 200 with the film formed substrate 200 and the vapor deposition particle ejecting device 1B fixed.

In FIG. 9, the relative film thickness indicated by the first host component indicates the relative film thickness of the vapor deposition film formed by the host ejected from the nozzle 12 of the first vapor deposition source 10. The relative film thickness indicated by the second host component indicates the relative film thickness of the vapor deposition film formed by the host ejected from the nozzle 32 of the third vapor deposition source 30. The relative film thickness indicated by the host combined component indicates the relative film thickness of a vapor deposition film formed by host ejected from the first vapor deposition source 10 and host ejected from the second vapor deposition source 20.

In Comparative Example 2, the first vapor deposition source 10 and the third vapor deposition source 30 sandwich the second vapor deposition source 20′ with the nozzles 12 and 32 each inclined, relative to the film formed substrate 200, in the direction toward the second vapor deposition source 20′. Thus, as illustrated in FIG. 9, the directivity of the combined component including the hosts ejected from the nozzles 12 and 32 in the Y-axis direction can be set to be closer to the directivity of the dopant ejected from the nozzle 24 in the Y-axis direction that in Comparative Example 1. Nevertheless, the host inherently has a low directivity, and thus the directivity of the combined component including the hosts in the Y-axis direction would not match the directivity of the dopant in the Y-axis direction as illustrated in FIG. 9.

FIG. 10 is a graph illustrating relationship between a distance from the center position C1 of the film formed substrate 200 in the Y-axis direction and a mix ratio of a dopant to a host in a thickness direction of a co-evaporation film including the host and the dopant formed as the vapor deposition film by the vapor deposition particle ejecting devices 1, 1A, and 1B according to Example 1 and Comparative Examples 1 and 2, with a mix ratio of the dopant to the host set to be 100% (that is, the mixture ratio of dopant/host=1). Also in FIG. 10, the coordinate origin corresponds to the center position C1 of the film formed substrate 200 immediately above the center position Y1 of the container section 21 in the Y-axis direction in the second vapor deposition source 20.

In Comparative Example 1, the host and the dopant would not be uniformly mixed in the Y-axis direction due to a large difference between the directivity of the combined component including the hosts ejected from the nozzles 12 and 32 in the Y-axis direction, and the directivity of the dopant ejected from the nozzle 24 in the Y-axis direction. Thus, Comparative Example 1 involves a notable variation of the mix ratio of the dopant to the host in the Y-axis direction as illustrated in FIG. 10.

In Comparative Example 2, as illustrated in FIG. 10, the variation of the mix ratio of the dopant to the host in the Y-axis direction can be reduced as compared with that in Example 1, but cannot be eliminated.

The variation is due to the film thickness distribution of the host and the dopant as a result of the fixed film forming as illustrated in FIG. 7 and FIG. 9. The variation would be a cause of property deterioration of the light-emitting element.

In contrast, in Example 1, the directivity of the dopant in the Y-axis direction and the directivity of the host in the Y-axis direction can substantially match as illustrated in FIG. 5. Thus, as illustrated in FIG. 10, the distribution of the mix ratio of the dopant to the host in the Y-axis direction can be stabilized to be constant. As a result, in Example 1, a risk of the dopant concentration at the time when the film forming starts (that is, an interface with a layer adjacent to the light emitting layer for carrying holes or the like) dropping below a set value can be reduced. Thus, with Example 1, productivity and yield can be improved.

Thus, the embodiment can provide the vapor deposition particle ejecting device 1 and the vapor deposition apparatus 100 as well as a vapor deposition film forming method with which the dopant can be uniformly dispersed in the host used in the co-evaporation as in Example 1 can be provided.

### Modified Example 1

In the embodiment, an example is described where the first vapor deposition source 10 and the third vapor deposition source 30 are each provided with the host nozzles 12, 32 linearly arranged in a single array (that is provided on the same axis), and the second vapor deposition source 20 is provided with the dopant nozzles 22 and the dopant nozzles 23 each linearly arranged in a single array. However, the embodiment described above is not limited thereto. The first vapor deposition source 10 and the third vapor deposition source 30 may each be provided with a plurality of linear arrays of the host nozzles 12, 32. Similarly, the second vapor deposition source 20 may be provided with a plurality of linear arrays of the dopant nozzles 22, 23.

### Modified Example 2

In the embodiment, an example is described where the vapor deposition film is a light-emitting layer in an organic EL element (Organic Light Emitting Diode (OLED)), for example. However, the embodiment described above is not limited thereto. The vapor deposition film may be a light-emitting layer in an inorganic light emitting diode (inorganic EL element) or a Quantum-dot Light Emitting Diode (QLED). The vapor deposition particle ejecting device 1 can be used for forming (producing) any co-evaporation film including host and dopant.

For example, the vapor deposition particle ejecting device 1 and the vapor deposition apparatus 100 can be suitably used for an apparatus for manufacturing an EL display device such as an organic EL display device including an OLED element and an inorganic EL display device including an inorganic light emitting diode, and a QLED display device including a QLED element.

### Modified Example 3

The nozzle inclination angle θ of the nozzle 22, 23 can be set to be larger for a smaller mix ratio of the dopant to the host, when the vapor deposition film is manufactured.

The vapor deposition particle ejecting device 1 may include a second vapor deposition source 20 including nozzles 22 and 23 that are fixed to the container section 21 and have the nozzle inclination angle θ corresponding to the type of a light emitting material used for the dopant, or may include a second vapor deposition source 20 including movable nozzles 22 and 23 so that the nozzle inclination angle θ can be changed in accordance with the type of the light emitting material used for the dopant. The nozzle 12 of the first vapor deposition source 10 and the nozzle 32 of the third vapor deposition source 30 may be fixed to the container section 11 or the container section 31 and may be provided in so that the nozzle inclination angle θ can be changed.

### Supplement

A vapor deposition particle ejecting device (1) according to an Aspect 1 of the disclosure includes a vapor deposition source for dopant (second vapor deposition source 20) ejecting a dopant as vapor deposition particles (212), and a first vapor deposition source for host (first vapor deposition source 10) and a second vapor deposition source for host (third vapor deposition source 30) ejecting a host as vapor deposition particles (vapor deposition particles 211 or 213) and are arranged side by side in a first direction (Y-axis direction) with the first vapor deposition source for host and the second vapor deposition source for host sandwiching the vapor deposition source for dopant. The first vapor deposition source for host is provided with a plurality of first nozzles (nozzles 12) linearly arranged along a second direction (X-axis direction) orthogonal to the first direction, the first nozzles being inclined toward the vapor deposition source for dopant. The second vapor deposition source for host is provided with a plurality of second nozzles (nozzles 32) arranged along the second direction, the second nozzles being inclined toward the vapor deposition source for dopant. The vapor deposition source for dopant is provided with a plurality of third nozzles (nozzles 23) linearly arranged along the second direction, the third nozzles being inclined toward the first vapor deposition source for host, and with a plurality of fourth nozzles (nozzles 22) linearly arranged along the second direction, the fourth nozzles being inclined toward the second vapor deposition source for host.

A vapor deposition particle ejecting device according to an Aspect 2 of the disclosure is such that, in the Aspect 1, the first nozzles, the fourth nozzles, the third nozzles, and the second nozzles may be arranged in this order in the first direction.

A vapor deposition particle ejecting device according to an Aspect 3 of the disclosure is such that, in the Aspect 1 or 2, the third nozzles and the fourth nozzles may be inclined to have nozzle axes thereof crossing each other.

A vapor deposition particle ejecting device according to an Aspect 4 of the disclosure is such that, in the Aspect 3, ejection ports (vapor deposition particle outlet 22a) of the third nozzles and ejection ports (vapor deposition particle outlet 23a) of the fourth nozzles may be arranged coaxially along the second direction.

A vapor deposition particle ejecting device according to an Aspect 5 of the disclosure is such that, in the Aspect 4, a first line (line L1) connecting centers of the ejection ports of the third nozzles to each other and a second line (line L2) connecting centers of the ejection ports of the fourth nozzles to each other may be the same line.

A vapor deposition particle ejecting device according to an Aspect 6 of the disclosure is such that, in any one of Aspects 3 to 5, the vapor deposition source for dopant may include a container section (21) having one surface provided with a groove section (21a) having inclined surfaces facing each other, the container section incorporating the dopant, the plurality of third nozzle sections may stand on one of the inclined surfaces to be orthogonal to the inclined surface, and the plurality of fourth nozzle sections may stand on another one of the inclined surfaces to be orthogonal to the inclined surface.

A vapor deposition particle ejecting device according to an Aspect 7 of the disclosure is such that, in any one of Aspects 1 to 6, an inclination angle (nozzle inclination angle θ) of the first nozzles and inclination angle (nozzle inclination angle θ) of the second nozzles may be same.

A vapor deposition particle ejecting device according to an Aspect 8 of the disclosure is such that, in any one of Aspects 1 to 7, an inclination angle (nozzle inclination angle θ) of the third nozzles and inclination angle (nozzle inclination angle θ) of the fourth nozzles may be same.

A vapor deposition particle ejecting device according to an Aspect 9 of the disclosure is such that, in any one of Aspects 1 to 8, the first nozzles and the second nozzles may have a same nozzle diameter and a same nozzle length.

A vapor deposition particle ejecting device according to an Aspect 10 of the disclosure is such that, in any one of Aspects 1 to 9, the third nozzles and the fourth nozzles may have a same nozzle diameter and a same nozzle length.

A vapor deposition particle ejecting device according to an Aspect 11 of the disclosure is such that, in any one of Aspects 1 to 10, a nozzle diameter of the third nozzles and a nozzle diameter of the fourth nozzles may be smaller than a nozzle diameter of the first nozzles and a nozzle diameter of the second nozzles.

A vapor deposition apparatus (100) according to an Aspect 12 of the disclosure includes the vapor deposition particle ejecting device according to any one of Aspects 1 to 11. The host and the dopant are co-evaporated by moving at least one of the vapor deposition particle ejecting device and a film formed substrate (200), arranged while facing each other, along the first direction relative to the other.

A vapor deposition apparatus according to an Aspect 13 of the disclosure, in the Aspect 12, may further include a limiting plate unit (40) including a plurality of limiting plates (41) provided between the vapor deposition particle ejecting device and the film formed substrate, and along the second direction while being separated from each other to partition the vapor deposition sources (that is, between the first vapor deposition source for host and the vapor deposition source for dopant, and between the vapor deposition source for dopant and the second vapor deposition source for host) in plan view, the limiting plates limiting a passage angle of the vapor deposition particles (211, 212, 213) ejected from each of the nozzles (12, 22, 23, 32).

A vapor deposition film forming method according to an Aspect 14 of the disclosure for forming a vapor deposition film including a host and a dopant on a film formed substrate (200), the method including co-evaporating the host and the dopant by moving at least one of the vapor deposition particle ejecting device according to any one of Aspects 1 to 11 and the film formed substrate, arranged while facing each other, along the first direction relative to the other.

A vapor deposition film forming method according to an Aspect 15 of the disclosure is such that, in the Aspect 14, inclination angles of the third nozzles and the fourth nozzles may be set to be larger for a smaller mix ratio of the dopant to the host.

### REFERENCE SIGNS LIST

1 Vapor deposition particle ejecting device
10 First vapor deposition source (first vapor deposition source for host)
11, 21, 31 Container section
12 Nozzle (first nozzle)
12a, 22a, 23a, 32a Vapor deposition particle outlet (ejection port)
20 Second vapor deposition source (vapor deposition source for dopant)
21a Groove section
22 Nozzle (fourth nozzle)
23 Nozzle (third nozzle)
30 Third vapor deposition source
32 Nozzle (second nozzle)
40 Limiting plate unit
41 Limiting plate
100 Vapor deposition apparatus
200 Film formed substrate
211, 212, 213 Vapor deposition particle

1. A vapor deposition particle ejecting device comprising:
a vapor deposition source for dopant ejecting a dopant as vapor deposition particles; and
a first vapor deposition source for host and a second vapor deposition source for host ejecting a host as vapor deposition particles and are arranged side by side in a first direction with the first vapor deposition source for host and the second vapor deposition source for host sandwiching the vapor deposition source for dopant,
wherein the first vapor deposition source for host is provided with a plurality of first nozzles linearly arranged along a second direction orthogonal to the first direction, the first nozzles being inclined toward the vapor deposition source for dopant,
the second vapor deposition source for host is provided with a plurality of second nozzles arranged along the second direction, the second nozzles being inclined toward the vapor deposition source for dopant,
the vapor deposition source for dopant is provided with a plurality of third nozzles linearly arranged along the second direction, the third nozzles being inclined toward the first vapor deposition source for host, and with a plurality of fourth nozzles linearly arranged along the second direction, the fourth nozzles being inclined toward the second vapor deposition source for host,
the third nozzles and the fourth nozzles are inclined to have nozzle axes thereof crossing each other,
ejection ports of the third nozzles and ejection ports of the fourth nozzles are arranged coaxially along the second direction, and
a first line connecting centers of the ejection ports of the third nozzles to each other and a second line connecting centers of the ejection ports of the fourth nozzles to each other are the same line.

2-5. (canceled)

6. The vapor deposition particle ejecting device according to claim 1,
wherein the vapor deposition source for dopant includes a container section having one surface provided with a groove section having inclined surfaces facing each other,
the container section incorporating the dopant,
the plurality of third nozzle sections stand on one of the inclined surfaces to be orthogonal to the inclined surface, and
the plurality of fourth nozzle sections stand on another one of the inclined surfaces to be orthogonal to the inclined surface.

7. The vapor deposition particle ejecting device according to claim 1,
wherein an inclination angle of the first nozzles and an inclination angle of the second nozzles are same.

8. The vapor deposition particle ejecting device according to claim 1,
wherein an inclination angle of the third nozzles and an inclination angle of the fourth nozzles are same.

9. The vapor deposition particle ejecting device according to claim 1,
wherein the first nozzles and the second nozzles have a same nozzle diameter and a same nozzle length.

10. The vapor deposition particle ejecting device according to claim 1,
wherein the third nozzles and the fourth nozzles have a same nozzle diameter and a same nozzle length.

11. The vapor deposition particle ejecting device according to claim 1,
wherein a nozzle diameter of the third nozzles and a nozzle diameter of the fourth nozzles are smaller than a nozzle diameter of the first nozzles and a nozzle diameter of the second nozzles.

12. A vapor deposition apparatus comprising:
the vapor deposition particle ejecting device according to claim 1,
wherein the host and the dopant are co-evaporated by moving at least one of the vapor deposition particle ejecting device and a film formed substrate, arranged while facing each other, along the first direction relative to the other.

13. The vapor deposition apparatus according to claim 12 further comprising:
a limiting plate unit including a plurality of limiting plates provided between the vapor deposition particle ejecting device and the film formed substrate, and along the second direction while being separated from each other to partition the vapor deposition sources in plan view, the limiting plates limiting a passage angle of the vapor deposition particles ejected from each of the nozzles.

14. A vapor deposition film forming method for forming a vapor deposition film including a host and a dopant on a film formed substrate, the method comprising:
co-evaporating the host and the dopant by moving at least one of the vapor deposition particle ejecting device according to claim 1 and the film formed substrate, arranged while facing each other, along the first direction relative to the other.

15. The vapor deposition film forming method according to claim 14,
wherein inclination angles of the third nozzles and the fourth nozzles are set to be larger for a smaller mix ratio of the dopant to the host.

16. A vapor deposition particle ejecting device comprising:
a vapor deposition source for dopant ejecting a dopant as vapor deposition particles; and
a first vapor deposition source for host and a second vapor deposition source for host ejecting a host as vapor deposition particles and are arranged side by side in a first direction with the first vapor deposition source for host and the second vapor deposition source for host sandwiching the vapor deposition source for dopant,
wherein the first vapor deposition source for host is provided with a plurality of first nozzles linearly arranged along a second direction orthogonal to the first direction, the first nozzles being inclined toward the vapor deposition source for dopant,
the second vapor deposition source for host is provided with a plurality of second nozzles arranged along the second direction, the second nozzles being inclined toward the vapor deposition source for dopant,
the vapor deposition source for dopant is provided with a plurality of third nozzles linearly arranged along the second direction, the third nozzles being inclined toward the first vapor deposition source for host, and with a plurality of fourth nozzles linearly arranged along the second direction, the fourth nozzles being inclined toward the second vapor deposition source for host,
the third nozzles and the fourth nozzles are inclined to have nozzle axes thereof crossing each other,
the vapor deposition source for dopant includes a container section having one surface provided with a groove section having inclined surfaces facing each other, the container section incorporating the dopant,
the plurality of third nozzle sections stand on one of the inclined surfaces to be orthogonal to the inclined surface, and
the plurality of fourth nozzle sections stand on another one of the inclined surfaces to be orthogonal to the inclined surface.

17. The vapor deposition particle ejecting device according to claim 16,
wherein the first nozzles, the fourth nozzles, the third nozzles, and the second nozzles are arranged in this order in the first direction.

18. The vapor deposition particle ejecting device according to claim 16,
wherein ejection ports of the third nozzles and ejection ports of the fourth nozzles are arranged coaxially along the second direction.

19. A vapor deposition apparatus comprising:
the vapor deposition particle ejecting device according to claim 16,
wherein the host and the dopant are co-evaporated by moving at least one of the vapor deposition particle ejecting device and a film formed substrate, arranged while facing each other, along the first direction relative to the other.

20. A vapor deposition film forming method for forming a vapor deposition film including a host and a dopant on a film formed substrate, the method comprising:
co-evaporating the host and the dopant by moving at least one of the vapor deposition particle ejecting device according to claim 16 and the film formed substrate, arranged while facing each other, along the first direction relative to the other.

21. The vapor deposition film forming method according to claim 20,
wherein inclination angles of the third nozzles and the fourth nozzles are set to be larger for a smaller mix ratio of the dopant to the host.

22. A vapor deposition film forming method for forming a vapor deposition film including a host and a dopant on a film formed substrate, using a vapor deposition particle ejecting device comprising:
a vapor deposition source for dopant ejecting a dopant as vapor deposition particles; and
a first vapor deposition source for host and a second vapor deposition source for host ejecting a host as vapor deposition particles and are arranged side by side in a first direction with the first vapor deposition source for host and the second vapor deposition source for host sandwiching the vapor deposition source for dopant,
wherein the first vapor deposition source for host is provided with a plurality of first nozzles linearly arranged along a second direction orthogonal to the first direction, the first nozzles being inclined toward the vapor deposition source for dopant,
the second vapor deposition source for host is provided with a plurality of second nozzles arranged along the second direction, the second nozzles being inclined toward the vapor deposition source for dopant, and
the vapor deposition source for dopant is provided with a plurality of third nozzles linearly arranged along the second direction, the third nozzles being inclined toward the first vapor deposition source for host, and with a plurality of fourth nozzles linearly arranged along the second direction, the fourth nozzles being inclined toward the second vapor deposition source for host,
the method comprising
co-evaporating the host and the dopant by moving at least one of the vapor deposition particle ejecting device and the film formed substrate, arranged while facing each other, along the first direction relative to the other,
wherein inclination angles of the third nozzles and the fourth nozzles are set to be larger for a smaller mix ratio of the dopant to the host.

23. The vapor deposition film forming method according to claim 22,
wherein the first nozzles, the fourth nozzles, the third nozzles, and the second nozzles are arranged in this order in the first direction.

24. The vapor deposition film forming method according to claim 22,
wherein the third nozzles and the fourth nozzles are inclined to have nozzle axes thereof crossing each other.
